(19) United States
(12) Patent Application Publication
(10) Pub. No.: US 2026/0197936 A1
(43) Pub. Date: Jul. 9, 2026

(54) FLEXIBLE CIRCUIT BOARD AND DISPLAY DEVICE

(71) Applicants: Chengdu BOE Optoelectronics Technology Co., Ltd., Chengdu, Sichuan (CN); BOE TECHNOLOGY GROUP CO., LTD., Beijing (CN)

(72) Inventors: Xingyue LIN, Beijing (CN); Xuelian JI, Beijing (CN); Yicai ZHANG, Beijing (CN); Tianma LI, Beijing (CN); Dake WANG, Beijing (CN); Yong HUANG, Beijing (CN); Yuangang ZHU, Beijing (CN); Rui CHEN, Beijing (CN); Zhengguang ZHANG, Beijing (CN)

(73) Assignees: Chengdu BOE Optoelectronics Technology Co., Ltd., Chengdu, Sichuan (CN); BOE TECHNOLOGY GROUP CO., LTD., Beijing (CN)

(21) Appl. No.: 18/730,095

(22) PCT Filed: Mar. 31, 2023
(86) PCT No.: PCT/CN2023/085517

§ 371 Date: Jul. 18, 2024

(51) Int. Cl. H05K 1/02; H05K 1/11

(52) U.S. Cl. CPC H05K 1/028; H05K 1/0224; H05K 1/118; H05K 2201/10128

(57) ABSTRACT

A flexible circuit board and a display device in the flexible circuit board, the first pad structure is in the first pad region, the second pad structure is in the second pad region, the plurality of signal transmission lines are in the transmission line region, and the transmission line region includes a first single-layer region and a first double-layer region arranged along the first direction; in the first single-layer region, the first side of the substrate layer is provided with the first conductive layer, and a second side of the substrate layer is not provided with a conductive structure, in the first double-layer region, the first side of the substrate layer is provided with the first conductive layer, and the second side of the substrate layer is provided with a second conductive layer, the second side and the first side are opposite sides of the substrate layer.

### TECHNICAL FIELD

Embodiments of the present disclosure relate to a flexible circuit board and a display device.

### BACKGROUND

In the display device, for narrow frame design, the driving circuit board of the display panel is usually set at the backlight side of the display panel, and then the bonding region on the light-emitting side of the display panel is connected with the driving circuit board at the backlight side of the display panel through a curved flexible circuit board.

On the other hand, as the size and resolution of the display device continue to increase, the frequency of the display signal also increases. Therefore, it is needed to use a high-frequency signal transmission line (such as LVDS/EDP transmission line) to transmit the display signal, with clock frequency typically ranging from tens to hundreds of MHz.

In the process of high-frequency signal transmission, the signal or electromagnetic wave must propagate along a transmission path with uniform impedance. Once there is impedance mismatch or discontinuity in the transmission path, a part of the signal or electromagnetic wave will be reflected back to the transmitting terminal, and the remaining part will continue to be transmitted to the receiving terminal.

### SUMMARY

Embodiments of the present disclosure provide a flexible circuit board and a display device. By providing the first single-layer region and the first double-layer region in the transmission line region, the flexible circuit board can be bent or curved in the first single-layer region, thereby having good bending performance and avoiding significant stress or fracture in the first single-layer region. At the same time, the flexible circuit board can also use the second conductive layer in the first double-layer region to provide electromagnetic protection and impedance matching for signal transmission lines, thereby avoiding display defects caused by poor data transmission stability, improving the anti-electromagnetic interference ability and electromagnetic compatibility (EMC performance) of the flexible circuit board, and allowing the flexible circuit board to have a wider range of applications and scenarios.

At least one embodiment of the present disclosure provides a flexible circuit board, which includes: a substrate layer, comprising a first pad region, a second pad region, and a transmission line region between the first pad region and the second pad region; and a first conductive layer, at a first side of the substrate layer and comprising a first pad structure, a second pad structure, and a plurality of signal transmission lines extending along a first direction, the first pad structure is in the first pad region, the second pad structure is in the second pad region, the plurality of signal transmission lines are in the transmission line region, and the transmission line region comprises a first single-layer region and a first double-layer region arranged along the first direction; in the first single-layer region, the first side of the substrate layer is provided with the first conductive layer, and a second side of the substrate layer is not provided with a conductive structure, in the first double-layer region, the first side of the substrate layer is provided with the first conductive layer, and the second side of the substrate layer is provided with a second conductive layer, the second side and the first side are opposite sides of the substrate layer.

For example, in the flexible circuit board provided by an embodiment of the present disclosure, at least part of the first single-layer region is a bending region, and at least part of the first double-layer region is a flat region.

For example, in the flexible circuit board provided by an embodiment of the present disclosure, the transmission line region further comprises: a second double-layer region, at a side of the first single-layer region away from the first double-layer region in the first direction, in the second double-layer region, the first side of the substrate layer is provided with the first conductive layer, and the second side of the substrate layer is provided with a third conductive layer.

For example, in the flexible circuit board provided by an embodiment of the present disclosure, the flexible circuit board is bent to form a U-shaped structure, the U-shaped structure comprises a first flat part, a second flat part, and a connection part between the first flat part and the second flat part, the connection part connects the first flat part and the second flat part to partially enclose a storage space; at least part of the first double-layer region is at the second flat part, at least part of the first single-layer region and at least part of the second double-layer region are at the connection part, at least part of the second double-layer region is at a bottom of the connection part away from the storage space, and at least part of the first single-layer region is between the bottom and the second flat part.

For example, in the flexible circuit board provided by an embodiment of the present disclosure, the third conductive layer comprises a first interconnection line extending along a second direction intersecting with the first direction; the plurality of signal transmission lines comprise a plurality of first signal transmission lines, the plurality of first signal transmission lines are configured to transmit same electrical signals, and the plurality of first signal transmission lines are respectively electrically connected with the first interconnection line.

For example, in the flexible circuit board provided by an embodiment of the present disclosure, the first signal transmission line is configured to transmit a ground signal.

For example, in the flexible circuit board provided by an embodiment of the present disclosure, the second conductive layer and the third conductive layer are arranged in a same layer.

For example, the flexible circuit board provided by an embodiment of the present disclosure further includes: a second single-layer region, between the second double-layer region and the first pad region; and a third single-layer region, between the first double-layer region and the second pad region.

For example, in the flexible circuit board provided by an embodiment of the present disclosure, the plurality of signal transmission lines comprise: a high-frequency signal transmission line, configured to transmit a high-frequency signal; and a plurality of first ground lines, two sides of the high-frequency signal transmission line in a second direction intersecting with the first direction are respectively provided with at least one of the plurality of first ground lines, in the first double-layer region, the second conductive layer is connected with first ground lines at two sides of the high-frequency signal transmission line through first via holes passing through the substrate layer.

For example, in the flexible circuit board provided by an embodiment of the present disclosure, the high-frequency signal transmission line comprises: a first high-frequency signal sub-line; and a second high-frequency signal sub-line, a polarity of a high-frequency signal on the first high-frequency signal sub-line is different from a polarity of a high-frequency signal on the second high-frequency signal sub-line.

For example, in the flexible circuit board provided by an embodiment of the present disclosure, the transmission line region further comprises: a third double-layer region, between the first double-layer region and the second double-layer region, and passing through the first single-layer region to be respectively connected with the first double-layer region and the second double-layer region, the first single-layer region is also at two sides of the third double-layer region in a second direction, and the second direction intersects with the first direction, in the third double-layer region, the first side of the substrate layer is provided with the first conductive layer, and the second side of the substrate layer is provided with a fourth conductive layer, the second conductive layer and the third conductive layer are connected through the fourth conductive layer, and are arranged in a same layer.

For example, in the flexible circuit board provided by an embodiment of the present disclosure, the plurality of signal transmission lines comprise: a high-frequency signal transmission line, configured to transmit a high-frequency signal; and a plurality of first ground lines, the high-frequency signal transmission line extends from the first double-layer region through the third double-layer region to the second double-layer region, and two sides of the high-frequency signal transmission line in the second direction intersecting with the first direction are respectively provided with at least one of the plurality of first ground lines; in the first double-layer region, the second conductive layer is connected with first ground lines at two sides of the high-frequency signal transmission line through first via holes passing through the substrate layer, in the third double-layer region, the fourth conductive layer is connected with the first ground lines at two sides of the high-frequency signal transmission line through second via holes passing through the substrate layer.

For example, the flexible circuit board provided by an embodiment of the present disclosure, further comprising: a first protection layer, in the transmission line region and at a side of the first conductive layer away from the substrate layer; a second protection layer, in the first double-layer region and at a side of the second conductive layer away from the substrate layer; and a first exposing opening, in the second protection layer and configured to expose the second conductive layer.

For example, the flexible circuit board provided by an embodiment of the present disclosure further includes: a conductive tape, at least partially at a side of the second protection layer away from the second conductive layer, and in contact with the second conductive layer through the first exposing opening, wherein the conductive tape is configured to be connected with a ground terminal.

For example, in the flexible circuit board provided by an embodiment of the present disclosure, the first exposing opening is at a side of a center of the first double-layer region close to the first single-layer region in the first direction.

For example, in the flexible circuit board provided by an embodiment of the present disclosure, the flexible circuit board comprises a plurality of first exposing openings arranged in a second direction intersecting with the first direction.

For example, in the flexible circuit board provided by an embodiment of the present disclosure, the plurality of signal transmission lines comprise a second ground line at an outermost side of the plurality of signal transmission lines; the first conductive layer further includes: a conductive grid, at a side of the second ground line away from a center of the plurality of signal transmission lines, and connected with the second ground line; and a protection line, at a side of the conductive grid away from the second ground line.

For example, the flexible circuit board provided by an embodiment of the present disclosure further includes: a first protection layer, in the transmission line region and at a side of the first conductive layer away from the substrate layer; a second protection layer, in the first double-layer region and at a side of the second conductive layer away from the substrate layer; and a second exposing opening, in the first protection layer and configured to expose the first conductive layer, an orthographic projection of the second exposing opening on the substrate layer respectively overlaps with an orthographic projection of the second ground line on the substrate layer and an orthographic projection of the conductive grid on the substrate layer.

For example, the flexible circuit board provided by an embodiment of the present disclosure further includes: a first electromagnetic shielding coating layer, at a side of the first protection layer away from the first conductive layer, and in contact with the second ground line and the conductive grid through the second exposing opening.

For example, in the flexible circuit board provided by an embodiment of the present disclosure, the first electromagnetic shielding coating layer is in the first double-layer region.

For example, the flexible circuit board provided by an embodiment of the present disclosure further includes: a third exposing opening, in the second protection layer and configured to expose the second conductive layer; and a second electromagnetic shielding coating layer, at a side of the second protection layer away from the second conductive layer, and in contact with the second conductive layer through the third exposing opening.

For example, in the flexible circuit board provided by an embodiment of the present disclosure, an orthographic projection of the third exposing opening on the substrate layer overlaps with an orthographic projection of the second exposing opening on the substrate layer.

For example, in the flexible circuit board provided by an embodiment of the present disclosure, the first pad structure comprises M first conductive pads, and the second pad structure comprises M second conductive pads; the plurality of signal transmission lines comprise a second signal transmission line, the second signal transmission line comprises a first end and a second end, the first end of the second signal transmission line comprises P branches, and the second end of the second signal transmission line comprises P branches; the P branches at the first end of the second signal transmission line are respectively connected with P first conductive pads, and the P branches at the second end of the second signal transmission line are respectively connected with P second conductive pads, P is a positive integer greater than or equal to 2 and less than M.

For example, in the flexible circuit board provided by an embodiment of the present disclosure, the first pad structure comprises M first conductive pads, and the second pad structure comprises N second conductive pads; the plurality of signal transmission lines comprise a third signal transmission line, the third signal transmission line comprises a first end and a second end, and the first end of the third signal transmission line comprises P branches; the P branches at the first end of the third signal transmission line are respectively connected with P first conductive pads, and the second end of the third signal transmission line is connected with one second conductive pad, P is a positive integer greater than or equal to 2 and less than N, and M is greater than N.

For example, in the flexible circuit board provided by an embodiment of the present disclosure, the first pad structure comprises M first conductive pads, and the second pad structure comprises Q second conductive pads; the plurality of signal transmission lines comprise: a fourth signal transmission line, extending from the first pad region to the first double-layer region, wherein the fourth signal transmission line comprises a first end in the first pad region and a second end in the first double-layer region; and a fifth signal transmission line, extending from the first pad region through the first double-layer region to the second pad region, and comprising a first end in the first pad region and a second end in the second pad region, the second conductive layer further comprises a transverse transmission line, the transverse transmission line is connected with the second end of the fourth signal transmission line through a third via hole passing through the substrate layer, and connected with the fifth signal transmission line through a fourth via hole passing through the substrate layer.

For example, in the flexible circuit board provided by an embodiment of the present disclosure, the substrate layer is a flexible substrate layer.

For example, in the flexible circuit board provided by an embodiment of the present disclosure, the second conductive layer comprises a conductive metal grid.

For example, in the flexible circuit board provided by an embodiment of the present disclosure, a material of the first conductive layer comprises copper, and a material of the second conductive layer comprises copper.

At least one embodiment of the present disclosure further provides a display device, including: a display panel, and any one of the abovementioned flexible circuit board.

For example, the display device provided by an embodiment of the present disclosure further includes: a backboard, at a side of the display panel; and a driving circuit board, at a side of the backboard away from the display panel, the display panel comprises a bonding region and a plurality of bonding pads in the bonding region, the backboard comprises a bottom frame, and the flexible circuit board is bent from the bonding region to a side of the backboard away from the display panel; the first pad structure is connected with the plurality of bonding pads, and the second pad structure is connected with the driving circuit board.

For example, in the display device provided by an embodiment of the present disclosure, at least part of the first double-layer region is at the side of the backboard away from the display panel, and at least part of the first single-layer region is a bending region surrounding the bottom frame.

### BRIEF DESCRIPTION OF DRAWINGS

In order to clearly illustrate technical solutions of the embodiments of the present disclosure, the drawings of the embodiments will be briefly described. It is obvious that the described drawings in the following are only related to some embodiments of the present disclosure and thus are not construed as any limitation to the present disclosure.

FIG. 1 is a schematic diagram of a display device.

FIG. 2 is a planar schematic diagram of a flexible circuit board provided by an embodiment of the present disclosure.

FIG. 3A is a cross-sectional schematic diagram of a flexible circuit board along a line AB in FIG. 2 provided by an embodiment of the present disclosure.

FIG. 3B is a cross-sectional schematic diagram of a flexible circuit board along a line CD in FIG. 2 provided by an embodiment of the present disclosure.

FIG. 4A is a schematic diagram of a flexible circuit board applied to a display device provided by an embodiment of the present disclosure.

FIG. 4B is a partial schematic diagram of a display device provided by an embodiment of the present disclosure.

FIG. 5 is a cross-sectional schematic diagram of another flexible circuit board along a line AB in FIG. 2 provided by an embodiment of the present disclosure.

FIG. 6 is a layout diagram of a flexible circuit board provided by an embodiment of the present disclosure.

FIG. 7 is a schematic diagram of a first conductive layer in a flexible circuit board provided by an embodiment of the present disclosure.

FIG. 8 is a schematic diagram of a second conductive layer in a flexible circuit board provided by an embodiment of the present disclosure.

FIG. 9 is a schematic diagram of a second conductive layer connected with a first ground line through a first via hole in a flexible circuit board provided by an embodiment of the present disclosure.

FIG. 10 is a schematic diagram of another flexible circuit board provided by an embodiment of the present disclosure.

FIG. 11 is a cross-sectional schematic diagram of a flexible circuit board along a line EF in FIG. 10 provided by an embodiment of the present disclosure.

FIG. 12 is a layout diagram of a flexible circuit board provided by an embodiment of the present disclosure.

FIG. 13A is a partial schematic diagram of a first pad structure in a flexible circuit board provided by an embodiment of the present disclosure.

FIG. 13B is a partial schematic diagram of a second pad structure in a flexible circuit board provided by an embodiment of the present disclosure.

FIG. 14A is a partial schematic diagram of a first pad structure in another flexible circuit board provided by an embodiment of the present disclosure.

FIG. 14B is a partial schematic diagram of a second pad structure in another flexible circuit board provided by an embodiment of the present disclosure.

FIG. 15 is a layout diagram of a flexible circuit board provided by an embodiment of the present disclosure.

FIG. 16 is a planar schematic diagram of a flexible circuit board provided by an embodiment of the present disclosure.

FIG. 17 is a cross-sectional schematic diagram of a flexible circuit board along a line GH in FIG. 16 provided by an embodiment of the present disclosure.

FIG. 18 is a planar schematic diagram of a flexible circuit board provided by an embodiment of the present disclosure.

FIG. 19 is a cross-sectional schematic diagram of a flexible circuit board along a line JK in FIG. 18 provided by an embodiment of the present disclosure.

FIG. 20A is a structural schematic diagram of a display device provided by an embodiment of the present disclosure.

FIG. 20B is a partial enlarged diagram of a display device provided by an embodiment of the present disclosure.

### DETAILED DESCRIPTION

In order to make objectives, technical details, and advantages of the embodiments of the present disclosure clearer, the technical solutions of the embodiments will be described in a clearly and fully understandable way in connection with the drawings related to the embodiments of the present disclosure. Apparently, the described embodiments are just a part but not all of the embodiments of the present disclosure. Based on the described embodiments herein, those skilled in the art can obtain other embodiment(s), without any inventive work, which should be within the scope of the present disclosure.

Unless otherwise defined, all the technical and scientific terms used herein have the same meanings as commonly understood by one of ordinary skill in the art to which the present disclosure belongs. The terms “first”, “second”, etc., which are used in the present disclosure, are not intended to indicate any sequence, amount or importance, but distinguish various components. Also, the terms “comprise,” “comprising,” “include,” “including,” etc., are intended to specify that the elements or the objects stated before these terms encompass the elements or the objects and equivalents thereof listed after these terms, but do not preclude the other elements or objects. The phrases “connect”, “connected”, etc., are not intended to define a physical connection or mechanical connection, but may include an electrical connection, directly or indirectly.

Unless otherwise defined, the features such as “parallel”, “vertical” and “identical” used in the embodiments of this disclosure all include cases such as “parallel”, “vertical” and “identical” in a strict sense, and cases such as “approximately parallel”, “approximately vertical” and “approximately identical” contain certain errors. For example, the above-mentioned “roughly” can mean that the difference of the compared objects is within 10% or 5% of the average value of the compared objects. When the number of one component or element is not specified in the following of the disclosed embodiment, it means that the component or element can be one or more, or can be understood as at least one. “at least one” means one or more, and “multiple” means at least two.

As the size and resolution of the display device continue to increase, the frequency of the display signal also increases. Therefore, it is needed to use a high-frequency signal transmission line (such as LVDS/EDP transmission line) to transmit the display signal, with clock frequency typically ranging from tens to hundreds of MHz.

To ensure the accuracy of the transmitted display data, the high-frequency signal transmission line requires high stability, while also reducing the reflection of the high-frequency signal to improve the electromagnetic compatibility (EMC performance) of the product. In the typical display device, for better flexibility, the single-layer flexible circuit board is usually used to connect the driving circuit board and the display panel, thereby transmitting the display data provided by the host to the display panel. At the same time, the flexible circuit board can be bent to place the driving circuit board at the backlight side of the display panel, thereby achieving a narrow frame design.

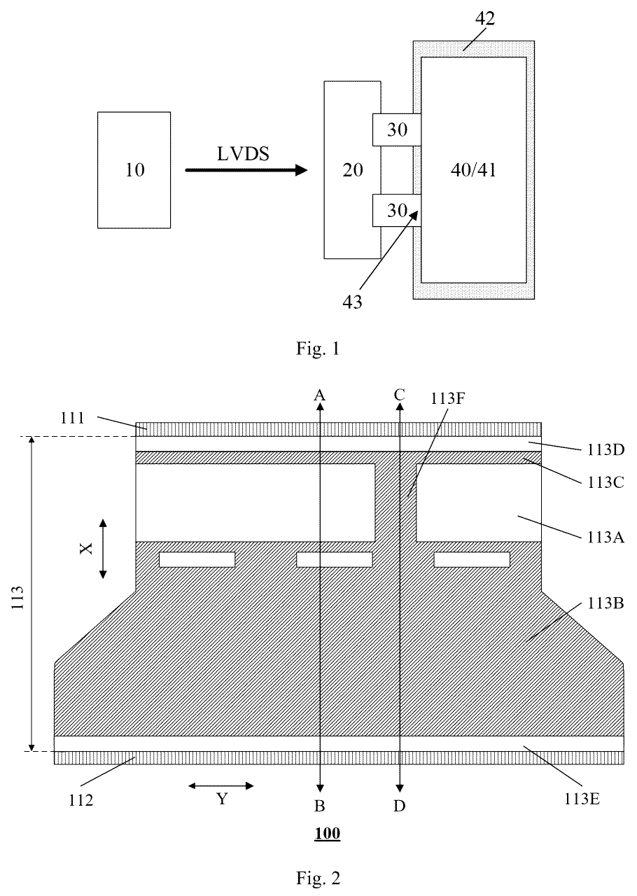

FIG. 1 is a schematic diagram of a display device. As illustrated by FIG. 1, the host 10 transmits the display data to the driving circuit board 20 through an LVDS transmission line. The driving circuit board 20 then transmits the display data to the display panel 40 through the flexible circuit board 30 to drive the display panel 40 to emit light and display. It should be noted that the display panel 40 includes a display region 41 and a peripheral region 42 surrounding the display region 41; the peripheral region 42 includes a bonding region 43, one end of the flexible circuit board 30 is connected with the driving circuit board 20, and the other end is connected with the bonding region 43 of the display panel 40.

However, the single-layer flexible circuit board only includes one conductive layer used to form signal transmission lines, and cannot be provided with other shielding layers or impedance matching layers (such as copper layers), so it is impossible to control the impedance of the high-frequency signal transmission line, which can easily lead to impedance mismatch of the high-frequency signal transmission line. Firstly, this impedance mismatch can affect the stability of data transmission and cause display anomalies; secondly, this impedance mismatch can also easily cause reflection of the high-frequency signal, resulting in poor performance of the flexible circuit board in both electromagnetic compatibility testing and anti-electromagnetic interference testing.

For the above issues, a double-layer flexible circuit board including two conductive layers can be used to connect the driving circuit board and the display panel. However, due to the increase in overall thickness of the double-layer flexible circuit board, the stress on pulling the display panel after bonding with the display panel is greater, which can easily pull up the part where the display panel is bonded to the flexible circuit board, thereby causing backlight to leak out from the pulled-up position, resulting in defects such as light leakage and Mura. On the other hand, the double-layer flexible circuit board has higher hardness and is prone to defects such as breakage when bent.

Embodiments of the present disclosure provide a flexible circuit board, the flexible circuit board includes a substrate layer and a first conductive layer, the substrate layer includes a first pad region, a second pad region, and a transmission line region between the first pad region and the second pad region; the first conductive layer is at a first side of the substrate layer and includes a first pad structure, a second pad structure, and a plurality of signal transmission lines extending along a first direction, the first pad structure is in the first pad region, the second pad structure is in the second pad region, the plurality of signal transmission lines are in the transmission line region, and the transmission line region includes a first single-layer region and a first double-layer region arranged along the first direction; in the first single-layer region, the first side of the substrate layer is provided with the first conductive layer, and a second side of the substrate layer is not provided with a conductive structure, in the first double-layer region, the first side of the substrate layer is provided with the first conductive layer, and the second side of the substrate layer is provided with a second conductive layer, the second side and the first side are opposite sides of the substrate layer. Therefore, by providing the first single-layer region and the first double-layer region in the transmission line region, the flexible circuit board can be bent or curved in the first single-layer region, thereby having good bending performance and avoiding significant stress or fracture in the first single-layer region. At the same time, the flexible circuit board can also use the second conductive layer in the first double-layer region to provide electromagnetic protection and impedance matching for signal transmission lines, thereby avoiding display defects caused by poor data transmission stability, improving the anti-electromagnetic interference ability and electromagnetic compatibility (EMC performance) of the flexible circuit board, and allowing the flexible circuit board to have a wider range of applications and scenarios.

Embodiments of the present disclosure provide further provide a display device, which includes a display panel and the above flexible circuit board. Therefore, on the one hand, the display device can avoid adverse effects such as light leakage caused by the high stress at the bonding position between the flexible circuit board and the display panel, and on the other hand, the display device also has strong electromagnetic compatibility and anti-electromagnetic interference ability.

Hereinafter, the flexible circuit board and the display device provided by the embodiments of the present disclosure will be described in detail with reference to the accompanying drawings.

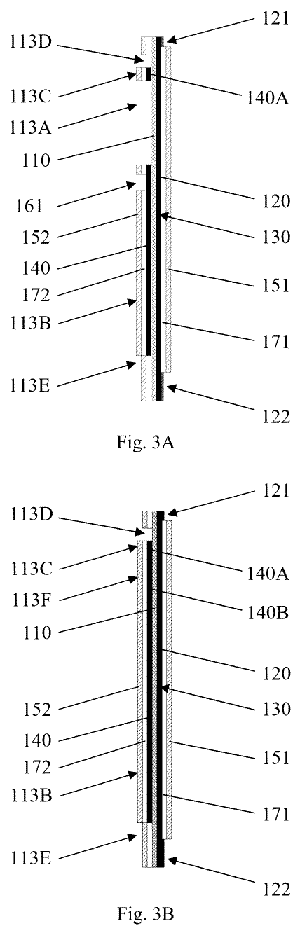

An embodiment of the present disclosure provides a flexible circuit board, FIG. 2 is a planar schematic diagram of a flexible circuit board provided by an embodiment of the present disclosure, FIG. 3A is a cross-sectional schematic diagram of a flexible circuit board along a line AB in FIG. 2 provided by an embodiment of the present disclosure, and FIG. 3B is a cross-sectional schematic diagram of a flexible circuit board along a line CD in FIG. 2 provided by an embodiment of the present disclosure.

As illustrated by FIG. 2 and FIG. 3A, the flexible circuit board 100 includes a substrate layer 110 and a first conductive layer 120; the substrate layer 110 includes a first pad region 111, a second pad region 112, and a transmission line region 113 located between the first pad region 111 and the second pad region 112. The first pad region 111, the transmission line region 113, and the second pad region 112 may be arranged along a first direction X; the first conductive layer 120 is located at the first side of the substrate layer 110 and includes a first pad structure 121, a second pad structure 122, and a plurality of signal transmission lines 130 extending along the first direction; the first pad structure 121 is located in the first pad region 111, the second pad structure 122 is located in the second pad region 112, and the plurality of signal transmission lines 130 are located in the transmission line region 113.

As illustrated by FIG. 2 and FIG. 3A, the transmission line region 113 includes a first single-layer region 113A and a first double-layer region 113B arranged along the first direction X. In the first single-layer region 113A, the first side of the substrate layer 110 is provided with the first conductive layer 120, and the second side of the substrate layer 110 is not provided with a conductive structure. In the first double-layer region 113B, the first side of the substrate layer 110 is provided with the first conductive layer 120, and the second side of the substrate layer 110 is provided with a second conductive layer 140. The second side and the first side are opposite sides of the substrate layer 110. It can be seen that the “single-layer” and “double-layer” in the “single-layer region” and “double-layer region” in the embodiments of the present disclosure refer to the number of conductive layers included in the corresponding region, and are not used to limit the number of other non-conductive layers.

In the flexible circuit board provided by the embodiments of the present disclosure, the first single-layer region only includes a single conductive layer, thus having good bending performance and less prone to fracture and generating excessive stress. Therefore, by providing the first single-layer region and the first double-layer region in the transmission line region, the flexible circuit board can be bent or curved in the first single-layer region, thereby having good bending performance and avoiding significant stress or fracture in the first single-layer region. At the same time, the flexible circuit board can also use the second conductive layer in the first double-layer region to provide electromagnetic protection and impedance matching for signal transmission lines, thereby avoiding display defects caused by poor data transmission stability, improving the anti-electromagnetic interference ability and electromagnetic compatibility (EMC performance) of the flexible circuit board, and allowing the flexible circuit board to have a wider range of applications and scenarios.

For example, the substrate layer may be a flexible substrate layer, and the material of the flexible substrate layer may be the flexible material such as polyimide. The material of the first conductive layer may be the conductive metal material such as copper, aluminum, silver, etc. The material of the second conductive layer may also be the conductive metal material such as copper, aluminum, silver, etc.

In some examples, because the first single-layer region 113A only includes one conductive layer (i.e., the first conductive layer 120) and has good bending or curving performance, at least part of the first single-layer region can serve as a bending region; that is to say, bending or curving process can be performed in the first single-layer region. The first double-layer region 113B includes two conductive layers (i.e., the first conductive layer and the second conductive layer), so at least part of the first double-layer region can serve as a flat region.

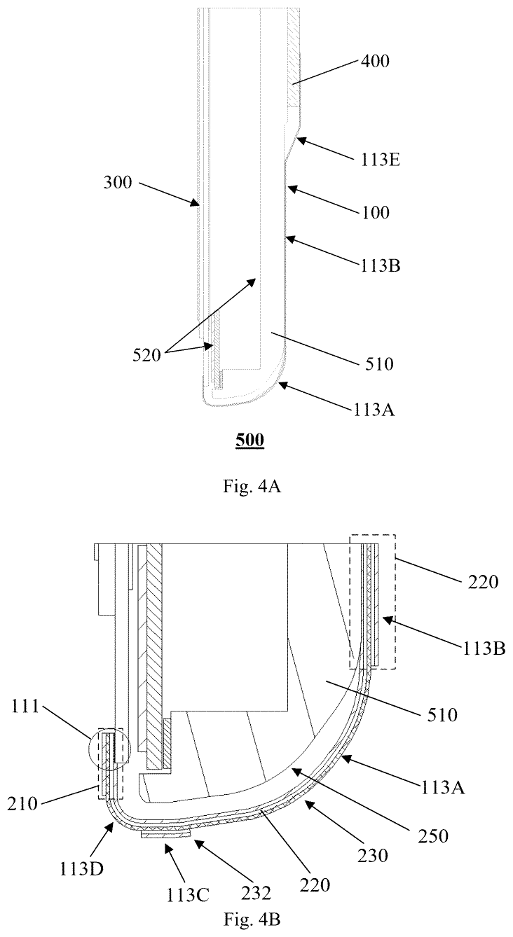

FIG. 4A is a schematic diagram of a flexible circuit board applied to a display device provided by an embodiment of the present disclosure, and FIG. 4B is a partial schematic diagram of a display device provided by an embodiment of the present disclosure. As illustrated by FIG. 4A and FIG. 4B, the display device 500 includes a display panel 300, a driving circuit board 400, and the above flexible circuit board 100; the driving circuit board 400 is located at the backlight side of the display panel 300. One end of the flexible circuit board 100 is bonded to the bonding region of the display panel 300, and then bent to allow the other end to be connected with the driving circuit board 400. Therefore, the driving circuit board 400 can transmit display data to the display panel 300 through the flexible circuit board 100 to drive the display panel 300 to emit light and display. Moreover, because the driving circuit board 400 is located at the backlight side of the display panel 300, and the flexible circuit board 100 is connected with the display panel 300 and the driving circuit board 400 through bending, the driving circuit board 400 does not occupy too much area, thereby achieving a narrow frame design.

As illustrated by FIG. 4A and FIG. 4B, the first single-layer region 113A of the flexible circuit board 100 can serve as a bending part of the flexible circuit board 100, while the first double-layer region 113B can be a flat part of the flexible circuit board 100 located at the backlight side of the display panel 300. Therefore, the flexible circuit board can be designed differently for the bending part and flat part, that is, by using different numbers of conductive layers to make the flexible circuit board have good bending performance, strong anti-electromagnetic interference ability, and electromagnetic compatibility.

On the other hand, because the flexible circuit board 100 uses the first single-layer region 113A as the bending part, the stress generated by the first single-layer region 113A is relatively small, which will not cause significant tension on the bonding region of the display panel 300, thus avoiding the exposure of backlight below the display panel 300 to cause defects such as light leakage and Mura.

It is worth noting that the second conductive layer 140 of the first double-layer region 113B in the flexible circuit board 100 provided by the embodiments of the present disclosure can not only be used for electromagnetic protection and impedance matching of the signal transmission line 130, but also for other functions. For example, the second conductive layer 140 may be provided with a conductive structure connected with part of the signal transmission lines 130 to reduce resistance; alternatively, the second conductive layer 140 may be provided with a conductive structure to electrically connect a plurality of signal transmission lines 130 that transmit the same signal to improve the uniformity and stability of the signal.

In some examples, as illustrated by FIG. 2 and FIG. 3A, the transmission line region 113 further includes a second double-layer region 113C, the second double-layer region 113C is located at the side of the first single-layer region 113A away from the first double-layer region 113B in the first direction; that is to say, the first single-layer region 113A is provided between the first double-layer region 113B and the second double-layer region 113C; in the second double-layer region 113C, the first side of the substrate layer 110 is provided with the first conductive layer 120, and the second side of the substrate layer 110 is provided with the third conductive layer 140A. Therefore, the flexible circuit board 100 can use other relatively flat parts to arrange the second double-layer region 113C mentioned above, thereby using the third conductive layer 140A in the second double-layer region 113C to provide electromagnetic protection and impedance matching for the signal transmission lines, thereby avoiding display defects caused by poor data transmission stability, and further improving the anti-electromagnetic interference ability and electromagnetic compatibility (EMC performance) of the flexible circuit board 100.

In some examples, the second conductive layer 140 and the third conductive layer 140A are arranged in the same layer. That is to say, the second conductive layer 140 and the third conductive layer 140A can be formed of the same conductive material layer through the same patterning process. Of course, the embodiments of the present disclosure include but are not limited thereto, the second conductive layer 140 and the third conductive layer 140A may also be formed of different materials through different processes. It should be noted that even if the second conductive layer 140 and the third conductive layer 140A are formed of different materials through different processes, both the second conductive layer 140 and the third conductive layer 140A can be located at the side of the substrate layer 110 away from the first conductive layer 120, or on the surface of the substrate layer 110 away from the first conductive layer 120.

In some examples, as illustrated by FIG. 4A and FIG. 4B, the flexible circuit board 100 is bent to form a U-shaped structure 200, the U-shaped structure 200 includes a first flat part 210, a second flat part 220, and a connection part 230 located between the first flat part 210 and the second flat part 220. The connection part 230 connects the first flat part 210 and the second flat part 220 to partially enclose a storage space 250; the storage space 250 can be used to arrange the backboard 510 and the backlight module 520; the backlight module 520 can adopt a side-in backlight module or a straight-down backlight module.

As illustrated by FIG. 4A and FIG. 4B, at least part of the first double-layer region 113B is located at the second flat part 220, at least part of the first single-layer region 113A and at least part of the second double-layer region 113C are located at the connection part 230, at least part of the second double-layer region 113C is located at the bottom 232 of the connection part 230 away from the storage space 250, and at least part of the first single-layer region 113A is located between the bottom 232 and the second flat part 220. Therefore, the flexible circuit board 100 can use the second flat part 220 to arrange the above first double-layer region 113B, use the bottom 232 of the connection part 230 to arrange the second double-layer region 113C, and use the first single-layer region 113A for bending or curving.

In some examples, as illustrated by FIG. 2 and FIG. 3A, the flexible circuit board 100 further includes a second single-layer region 113D and a third single-layer region 113E; the second single-layer region 113D is located between the second double-layer region 113C and the first pad region 111; the third single-layer region 113E is located between the first double-layer region 113B and the second pad region 112. The second single-layer region 113D can serve as a bending region between the bottom 232 of the connection part 230 away from the storage space 250 and the second flat part 220, and the third single-layer region 113E can serve as a transition region between the second pad region 112 and the first double-layer region 113B.

In some examples, as illustrated by FIG. 2 and FIG. 3A, the first pad region 111, the second single-layer region 113D, the second double-layer region 113C, the first single-layer region 113A, the first double-layer region 113B, and the third single-layer region 113E are sequentially arranged in the first direction. In this case, the size of the flexible circuit board in the first direction can be the sum of the sizes of the first pad region 111, the second single-layer region 113D, the second double-layer region 113C, the first single-layer region 113A, the first double-layer region 113B, and the third single-layer region 113E in the first direction.

It is worth noting that the above second double-layer region is the transition region between the two bending regions, and can also serve as a support to prevent the flexible circuit board from being excessively bent into a sharp angle and causing breakage of the signal transmission line. In addition, an interconnection line can be provided in the third conductive layer to connect signal transmission lines that transmit the same signal in the first conductive layer, thereby improving the uniformity of the signals on these signal transmission lines.

In some examples, as illustrated by FIG. 4A and FIG. 4B, the first pad region 111 is located at the first flat part 210; the second single-layer region 113D may be located at the rounded corner connection part between the first flat part 210 and the connection part 230, thereby having good bending performance and less prone to fracture or generating significant stress; the third single-layer region 113E can serve as a transition region between the second pad region 112 and the first double-layer region 113B.

For example, as illustrated by FIG. 4A and FIG. 4B, the length of the flexible circuit board 100 is equal to the sum of the length of the first pad region 111, the length of the second single-layer region 113D, the length of the second double-layer region 113C, the length of the first single-layer region 113A, the length of the first double-layer region 113B, the length of the third single-layer region 113E, and the length of the second pad region 112. Generally speaking, the length of the first pad region and the length of the second pad region are fixed values based on the type and model of the product.

For example, as illustrated by FIG. 4A and FIG. 4B, the second single-layer region 113D can be arranged in a ¼ arc shape, and its curvature radius is related to the shape of the backboard of the display device, which usually ranges from 0.6 to 0.8 millimeters.

For example, as illustrated by FIG. 4A and FIG. 4B, the second double-layer region 113C can serve as a transition region between the bent second single-layer region 113D and the bent first single-layer region 113A, thereby providing a support role to prevent the flexible circuit board 100 from being excessively bent into a sharp angle and causing signal transmission lines (such as copper wires) to break; meanwhile, the second double-layer region 113 is a flat part, with a length equal to the linear length of the bottom of the backboard.

For example, as illustrated by FIG. 4A and FIG. 4B, the first single-layer region 113A may also be arranged in an arc shape, with a shape similar to the rounded corner of the backboard, and its curvature radius is slightly larger than the curvature radius of the rounded corner of the backboard.

For example, as illustrated by FIG. 4A and FIG. 4B, the first double-layer region 113B starts from the end of the rounded corner of the backboard and ends at the driving circuit board 400.

In some examples, as illustrated by FIG. 2 and FIG. 3A, the flexible circuit board 100 further includes a first protection layer 151, a second protection layer 152, and a first exposing opening 161; the first protection layer 151 is located in the transmission line region 113, and at the side of the first conductive layer 120 away from the substrate layer 110; the second protection layer 152 is located in the first double-layer region 113B, and at the side of the second conductive layer 140 away from the substrate layer 110; the first exposing opening 161 is located in the second protection layer 152 and is configured to expose the second conductive layer 140, so that the second conductive layer 140 can be connected with an external conductive structure to provide voltage or electrical signals to various conductive structures in the second conductive layer 140.

In some examples, as illustrated by FIG. 2, the first exposing opening 161 is located at the side of the center of the first double-layer region 113B close to the first single-layer region 113A in the first direction. Of course, the embodiments of the present disclosure include but is not limited thereto, and the first exposing opening may also be provided in other positions.

For example, the size of the first exposing opening 161 in the first direction X may be 2 millimeters, and the size of the first exposing opening 161 in the second direction Y may be 10 millimeters. Of course, embodiments of the present disclosure include but is not limited thereto.

In some examples, as illustrated by FIG. 2, the flexible circuit board 100 includes a plurality of first exposing openings 161 arranged along the second direction Y intersecting with the first direction X. For example, the flexible circuit board 100 includes three first exposing openings 161 arranged at intervals along the second direction Y. Therefore, the second conductive layer can have a more uniform electrical potential.

In some examples, as illustrated by FIG. 3A, the flexible circuit board 100 may further include a first adhesive layer 171 and a second adhesive layer 172; the first adhesive layer 171 is located between the first conductive layer 120 and the first protection layer 151; the second adhesive layer 172 is located between the second conductive layer 140 and the second protection layer 152. It should be noted that when the second adhesive layer 172 is provided, the first exposing opening 161 also penetrates through the second adhesive layer 172 to expose the second conductive layer 140.

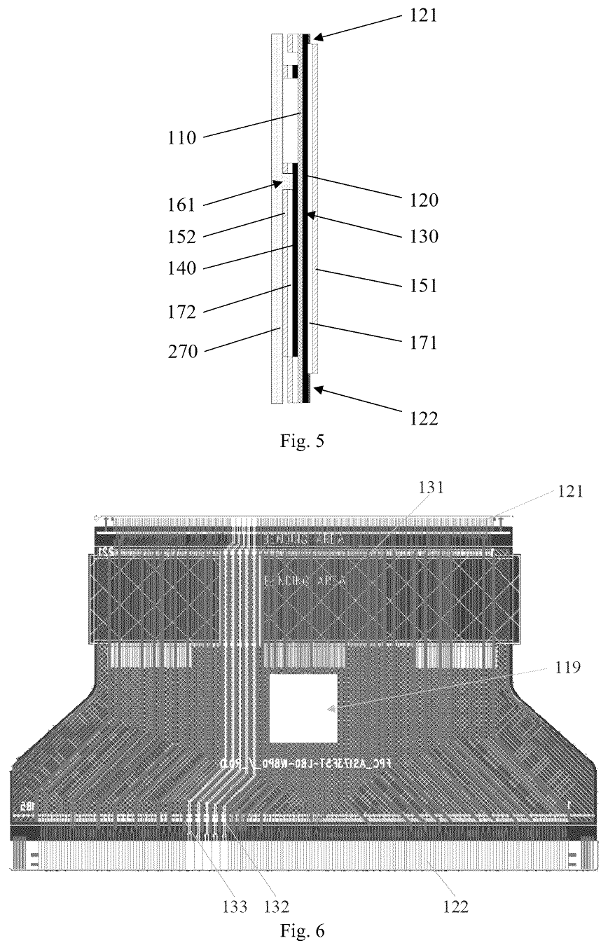

FIG. 5 is a cross-sectional schematic diagram of another flexible circuit board along a line AB in FIG. 2 provided by an embodiment of the present disclosure. As illustrated by FIG. 5, the flexible circuit board 100 further includes: a conductive tape 270, at least partially located at the side of the second protection layer 152 away from the second conductive layer 140, and in contact with the second conductive layer 140 through the first exposing opening 161, and the conductive tape 270 is configured to be connected with the ground terminal. Therefore, through the conductive tape 270 and the first exposing opening 161 mentioned above, the flexible circuit board 100 can ground the second conductive layer 140. It should be noted that when the flexible circuit board is applied to a display device, the above ground terminal may be the ground terminal on the display panel or the ground terminal on the driving circuit board.

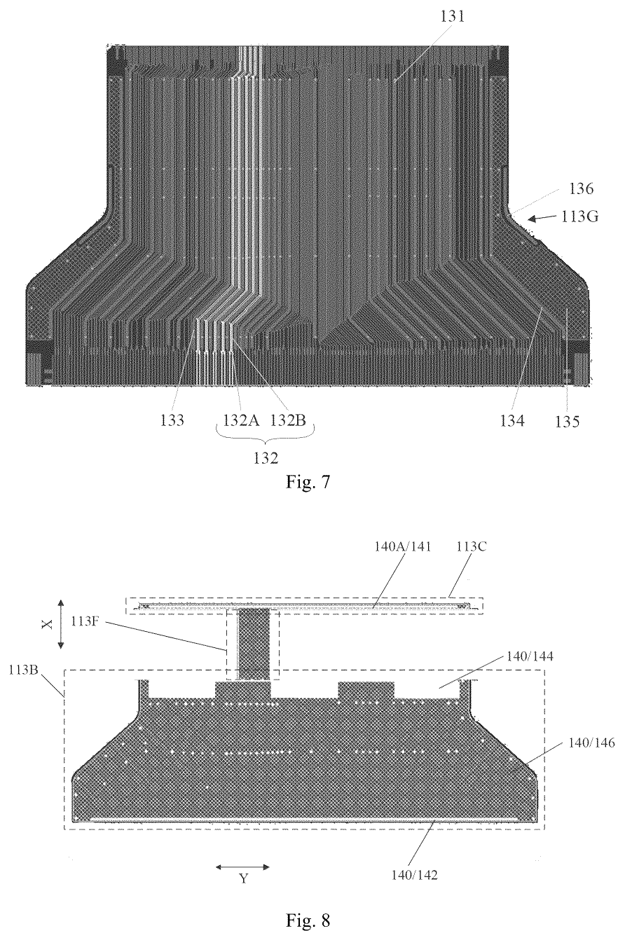

FIG. 6 is a layout diagram of a flexible circuit board provided by an embodiment of the present disclosure, FIG. 7 is a schematic diagram of a first conductive layer in a flexible circuit board provided by an embodiment of the present disclosure, and FIG. 8 is a schematic diagram of a second conductive layer in a flexible circuit board provided by an embodiment of the present disclosure. It should be noted that in the embodiment shown in FIGS. 6 to 8, the second conductive layer and the third conductive layer are arranged in the same layer, which can be considered as the same single conductive layer.

As illustrated by FIGS. 6 to 8, the third conductive layer 140A in the second double-layer region 113C of the flexible circuit board 100 includes a first interconnection line 141 extending along the second direction Y intersecting with the first direction X; in this embodiment, the third conductive layer 140A and the second conductive layer 140 are arranged in the same layer. The plurality of signal transmission lines 130 include a plurality of first signal transmission lines 131, which are configured to transmit the same electrical signal. The plurality of first signal transmission lines 131 are electrically connected with the first interconnection line 141, respectively. For example, the plurality of first signal transmission lines 131 may be connected with the first interconnection line 141 through via holes passing through the substrate layer 110. Therefore, the flexible circuit board 100 can improve the uniformity of signals on the plurality of first signal transmission lines 131.

In some examples, the first signal transmission line 131 is configured to transmit a ground signal, that is, the first signal transmission line 131 is a ground line. In this setting, because the second conductive layer 140 is usually grounded, the interconnection line is suitable for interconnecting a plurality of ground lines. It should be noted that the above ground line may include the first ground line and the second ground line mentioned below. Of course, the embodiments of the present disclosure include but are not limited thereto, the first signal transmission line 131 may also be configured to transmit signals such as power voltage and common voltage.

In some examples, as illustrated by FIGS. 6 to 8, the second conductive layer 140 of the first double-layer region 113B may also include a second interconnection line 142 for connecting the plurality of first signal transmission lines 131, thereby further improving the uniformity of signals on the plurality of first signal transmission lines 131.

For example, as illustrated by FIGS. 6 to 8, the second interconnection line 142 and the first interconnection line 141 are arranged parallel to each other. Of course, the embodiments of the present disclosure include but are not limited thereto, because the area of the first double-layer region 113B is relatively large, the second interconnection line may also choose different extension direction and type as needed.

In some examples, as illustrated by FIGS. 6 to 8, the plurality of signal transmission lines 130 include a high-frequency signal transmission line 132 and two first ground lines 133; the high-frequency signal transmission line 132 is configured to transmit a high-frequency signal; the two first ground lines 133 are located at two sides of the high-frequency signal transmission line 132 in the second direction Y intersecting with the first direction X; in the first double-layer region 113B, the second conductive layer 140 is connected with the two first ground lines 133 through first via holes passing through the substrate layer 110. That is to say, the plurality of signal transmission lines 130 include a high-frequency signal transmission line 132 and a plurality of first ground lines 133. Two sides of the high-frequency signal transmission line 132 are respectively provided with at least one first ground line 133 in the second direction intersecting with the first direction; in the first double-layer region 113B, the second conductive layer 140 is connected with the first ground lines 133 at two sides of the high-frequency signal transmission line 132 through the first via holes passing through the substrate layer.

Therefore, the first ground lines 133 at two sides of the high-frequency signal transmission line 132 and the second conductive layer 140 can provide a stable electromagnetic environment for the high-frequency signal transmission line 132, control the impedance of the high-frequency signal transmission line 132, thereby improving the stability of high-frequency signal transmission and avoiding reflection phenomena. On the other hand, the first ground lines 133 at two sides of the high-frequency signal transmission line 132 and the second conductive layer 140 can also form a shielding structure, thereby improving the anti-electromagnetic interference performance and electromagnetic compatibility.

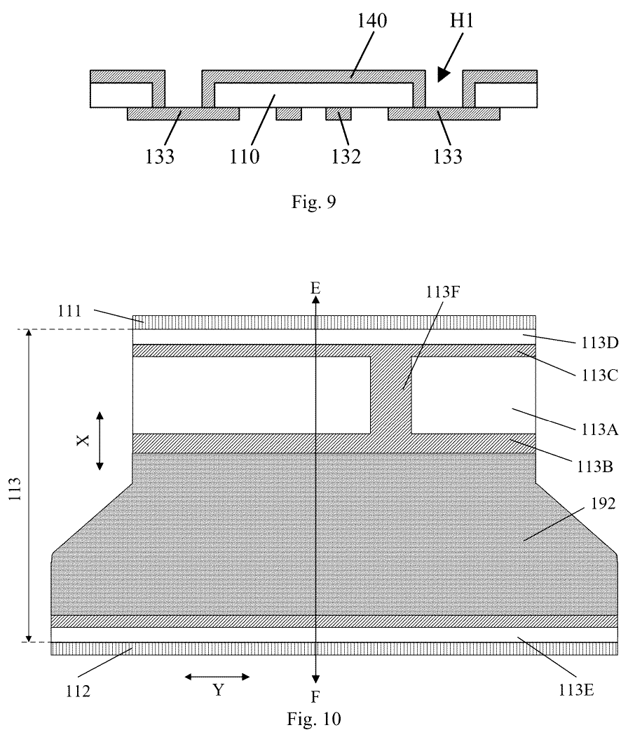

FIG. 9 is a schematic diagram of a second conductive layer connected with a first ground line through a first via hole in a flexible circuit board provided by an embodiment of the present disclosure. As illustrated by FIG. 9, the second conductive layer 140 is respectively connected with two first ground lines 133 through the first via holes H1 passing through the substrate layer 110. It should be noted that in the embodiments of the present disclosure, for the case where the second conductive layer is connected with other signal transmission lines through a via hole passing through the substrate layer, please refer to FIG. 9 and its related descriptions.

In some examples, as illustrated by FIGS. 6 to 8, the flexible circuit board 100 may include a plurality of high-frequency signal transmission lines 132, two first ground lines 133 are provided at two sides of each high-frequency signal transmission line 132, and two adjacent high-frequency signal transmission lines 132 may share one first ground line 133.

In some examples, as illustrated by FIGS. 6 to 8, the plurality of high-frequency signal transmission lines 132 and the plurality of first ground lines 133 are alternately arranged, and two first ground lines 133 are arranged at the outermost side of the plurality of high-frequency signal transmission lines 132.

In some examples, as illustrated by FIGS. 6 to 8, each high-frequency signal transmission line 132 includes a first high-frequency signal sub-line 132A and a second high-frequency signal sub-line 132B. The polarity of the high-frequency signal on the first high-frequency signal sub-line 132A and the polarity of the high-frequency signal on the second high-frequency signal sub-line 132B are different, thus having good transmission performance for high-frequency signals.

In some examples, as illustrated by FIG. 6, the substrate layer 110 may also include a marking region 119 for forming various markings.

In some examples, as illustrated by FIG. 2 and FIG. 3B, the transmission line region 113 further includes a third double-layer region 113F, the third double-layer region 113F is located between the first double-layer region 113B and the second double-layer region 113C, and passes through the first single-layer region 113A to be respectively connected with the first double-layer region 113B and the second double-layer region 113C. The first single-layer region 113A is also located at two sides of the third double-layer region 113F in the second direction, the second direction intersects with the first direction. In the third double-layer region 113F, the first side of the substrate layer 110 is provided with the first conductive layer 120, the second side of the substrate layer 110 is provided with the fourth conductive layer 140B, and the second conductive layer 140 and the third conductive layer 140A are connected through the fourth conductive layer 140B and are arranged in the same layer. In this way, the flexible circuit board 100 can form the third double-layer region 113F between the first double-layer region 113B and the second double-layer region 113C, thereby fully covering the high-frequency signal transmission line 132 in the first direction. Therefore, the third double-layer region 113F can further provide a stable electromagnetic environment for the high-frequency signal transmission line 132, improve the stability of high-frequency signal transmission, and avoid reflection phenomena. It should be noted that the third double-layer region is locally arranged in the second direction, and two sides of the third double-layer region are respectively provided with the first single-layer region, which can provide electromagnetic shielding for the high-frequency signal transmission line without affecting the bending performance of the flexible circuit board and avoid generating significant stress.

In some examples, as illustrated by FIGS. 6 to 8, the orthographic projection of the high-frequency signal transmission line 132 on the substrate layer 110 overlaps with the first double-layer region 113B, the second double-layer region 113C, and the third double-layer region 113F, respectively.

In some examples, as illustrated by FIGS. 6 to 8, the plurality of signal transmission lines 130 include a high-frequency signal transmission line 132 and two first ground lines 133; the high-frequency signal transmission line 132 is configured to transmit a high-frequency signal; the two first ground lines 133 are located at two sides of the high-frequency signal transmission line 132 in the second direction; the high-frequency signal transmission line 132 extends from the first double-layer region 113B through the third double-layer region 113F to the second double-layer region113C. In the first double-layer region 113B, the second conductive layer 140 is connected with the two first ground lines 133 through the first via holes passing through the substrate layer 110. In the third double-layer region 113F, the fourth conductive layer 140B is connected with the two first ground lines 133 through the second via holes passing through the substrate layer 110. That is to say, the plurality of signal transmission lines 130 include a high-frequency signal transmission line 132 and a plurality of first ground lines 133, the high-frequency signal transmission line 132 extends from the first double-layer region 113B through the third double-layer region 113F to the second double-layer region 113C, and two sides of the high-frequency signal transmission line 132 in the second direction intersecting with the first direction are respectively provided with at least one first ground line 133. In the first double-layer region 113B, the second conductive layer 140 is connected with the first ground lines 133 at two sides of the high-frequency signal transmission line 132 through the first via holes passing through the substrate layer 110. In the third double-layer region 113F, the fourth conductive layer 140B is connected with the first ground lines 133 at two sides of the high-frequency signal transmission line 132 through the second via holes passing through the substrate layer 110.

Therefore, the flexible circuit board can provide a continuous and stable electromagnetic environment for the high-frequency signal transmission line 132 through the first double-layer region 113B, the second double-layer region 113C, and the third double-layer region 113F mentioned above, thereby further providing a stable electromagnetic environment for the high-frequency signal transmission line 132, improving the stability of high-frequency signal transmission and avoiding reflection phenomena. It should be noted that, for the second via mentioned above, please refer to the relevant arrangements of the first via in FIG. 9.

In some examples, as illustrated by FIG. 6 and FIG. 7, the plurality of signal transmission lines 130 include a second ground line 134, which is located on the outermost side of the plurality of signal transmission lines 130; the first conductive layer 120 further includes a conductive grid 135 located at the side of the second ground line 134 away from the center of the plurality of signal transmission lines 130 and connected with the second ground line 134. The first conductive layer 120 further includes a protection line 136 located at the side of the conductive grid 135 away from the second ground line 134. In this way, the conductive grid 135 may be connected with the second ground line 134 to reduce the resistance of the second ground line 134 and fully utilize the space on the flexible circuit board 100. The protection line 136 is located at the side of the conductive grid 135 away from the second ground wire 134, which can protect the conductive grid 135 from being torn during production and bending process, and improve product yield.

In some examples, as illustrated by FIG. 6 and FIG. 7, the transmission line region 113 has a width expansion part 113G, and the protection line 136 is located at the edge of the width expansion part 113G, thereby preventing the conductive grid 135 from being torn during production and bending process, and improving product yield.

In some examples, as illustrated by FIG. 6 and FIG. 8, the second conductive layer 140 may further include a conductive block 144 and a conductive metal grid 146. The conductive block 144 is located at the first exposing opening 161 to be connected with the conductive tape 270, and the conductive metal grid 146 is located in regions of the first double-layer region 113B other than the first exposing opening 161.

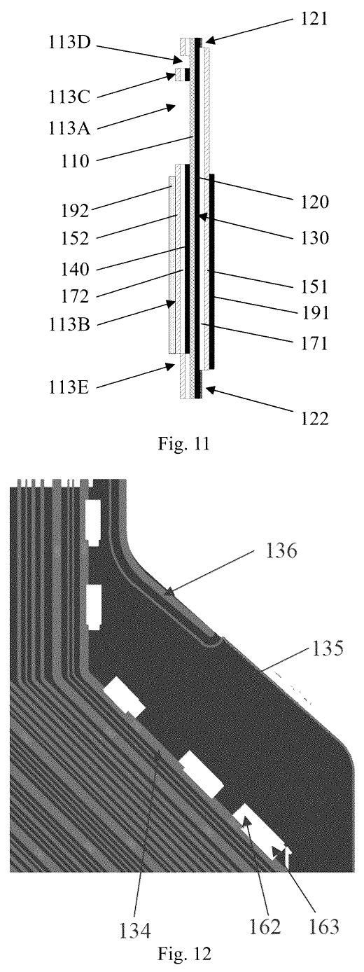

FIG. 10 is a schematic diagram of another flexible circuit board provided by an embodiment of the present disclosure, FIG. 11 is a cross-sectional schematic diagram of a flexible circuit board along a line EF in FIG. 10 provided by an embodiment of the present disclosure, and FIG. 12 is a layout diagram of a flexible circuit board provided by an embodiment of the present disclosure.

In some examples, as illustrated by FIGS. 10 to 12, the flexible circuit board 100 further includes a first protection layer 151, a second protection layer 152, and a second exposing opening 162; the first protection layer 151 is located in the transmission line region 113 and at the side of the first conductive layer 120 away from the substrate layer 110; the second protection layer 152 is located in the first double-layer region 113B and at the side of the second conductive layer 140 away from the substrate layer 110; the second exposing opening 162 is located in the first protection layer 151 and is configured to expose the first conductive layer 120; the orthographic projection of the second exposing opening 162 on the substrate layer 110 respectively overlaps with the orthographic projection of the second ground line 134 on the substrate layer 110 and the orthographic projection of the conductive grid on the substrate layer 110.

In some examples, as illustrated by FIGS. 10 to 12, the flexible circuit board 100 further includes a first electromagnetic shielding coating layer 191 located at the side of the first protection layer 151 away from the first conductive layer 120, and in contact with the second ground line 134 and the conductive grid through the second exposing opening 162. Therefore, the flexible circuit board 100 can further improve the anti-electromagnetic interference ability and electromagnetic compatibility of the flexible circuit board 100 through the first electromagnetic shielding coating layer 191 mentioned above.

In some examples, as illustrated by FIGS. 10 to 12, the first electromagnetic shielding coating layer 191 is only located in the first double-layer region 113B, thereby avoiding affecting the bending performance of the flexible circuit board 100.

In some examples, as illustrated by FIGS. 10 to 12, the flexible circuit board 100 further includes a third exposing opening 163 and a second electromagnetic shielding coating layer 192; the third exposing opening 163 is located in the second protection layer 152 and configured to expose the second conductive layer 140; the second electromagnetic shielding coating layer 192 is located at the side of the second protection layer 152 away from the second conductive layer 140, and in contact with the second conductive layer 140 through the third exposing opening 163. Therefore, the flexible circuit board 100 can further improve the anti-electromagnetic interference performance and electromagnetic compatibility of the flexible circuit board 100 through the third exposing opening 163 and the second electromagnetic shielding coating layer 192.

In some examples, as illustrated by FIGS. 10 to 12, the orthographic projection of the third exposing opening 163 on the substrate layer 110 overlaps with the orthographic projection of the second exposing opening 162 on the substrate layer 110, to allow the first electromagnetic shielding coating layer 191 and the second electromagnetic shielding coating layer 192 to be electrically connected with each other, thereby further improving the anti-electromagnetic interference performance and electromagnetic compatibility of the flexible circuit board.

It should be noted that although the flexible circuit board 100 shown in FIG. 11 is simultaneously provided with the first electromagnetic shielding coating layer 191 and the second electromagnetic shielding coating layer 192 mentioned above; but the embodiments of the present disclosure include but are not limited thereto, the flexible circuit board may only be provided with the first electromagnetic shielding coating layer or the second electromagnetic shielding coating layer.

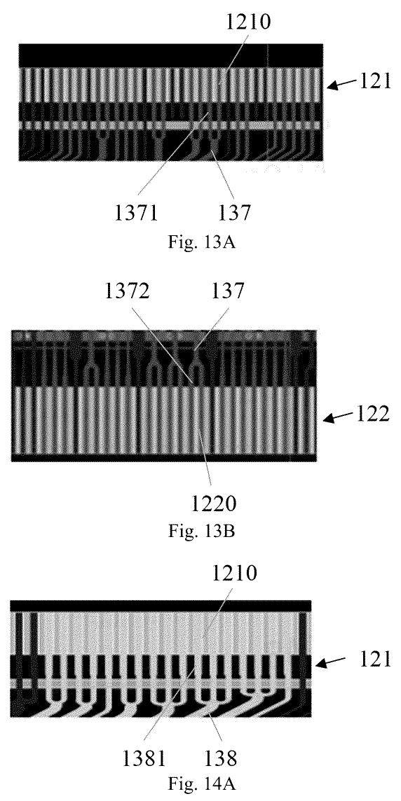

FIG. 13A is a partial schematic diagram of a first pad structure in a flexible circuit board provided by an embodiment of the present disclosure, and FIG. 13B is a partial schematic diagram of a second pad structure in a flexible circuit board provided by an embodiment of the present disclosure.

As illustrated by FIG. 13A and FIG. 13B, the first pad structure 121 includes M first conductive pads 1210; the second pad structure 122 includes M second conductive pads 1220; the plurality of signal transmission lines 130 include a second signal transmission line 137, the second signal transmission line 137 includes a first end and a second end, the first end of the second signal transmission line 137 includes P branches 1371, and the second end of the second signal transmission line 137 includes P branches 1372; the P branches 1371 at the first end of the second signal transmission line 137 are respectively connected with P first conductive pads 1210, and the P branches 1372 at the second end of the second signal transmission line 137 are respectively connected with P second conductive pads 1220. P is a positive integer greater than or equal to 2 and less than M. Therefore, the flexible circuit board 100 can reduce the number of signal transmission lines in the transmission line region 113 through the above structure, thereby making the signal transmission lines have a larger line width or increasing the spacing between signal transmission lines, and improving the stability of the flexible circuit board 100.

For example, as illustrated by FIG. 13A and FIG. 13B, the value of P may be 2. In this case, the first end of the second signal transmission line 137 includes two branches 1371, and the second end of the second signal transmission line 137 includes two branches 1372; the two branches 1371 at the first end of the second signal transmission line 137 are respectively connected with two first conductive pads 1210, and the two branches 1372 at the second end of the second signal transmission line 137 are respectively connected with two second conductive pads 1220. Of course, the embodiments of the present disclosure include but are not limited thereto, and the value of P may also be 3, 4, 5, 6, 7, 8, etc.

For example, the first conductive pad and the second conductive pad may be gold fingers, the width of the first conductive pad may be 0.09 millimeters, and the spacing between adjacent first conductive pads may be 0.09 millimeters; the width of the second conductive pad be 0.15 millimeters, and the spacing between adjacent second conductive pads is 0.15 millimeters.

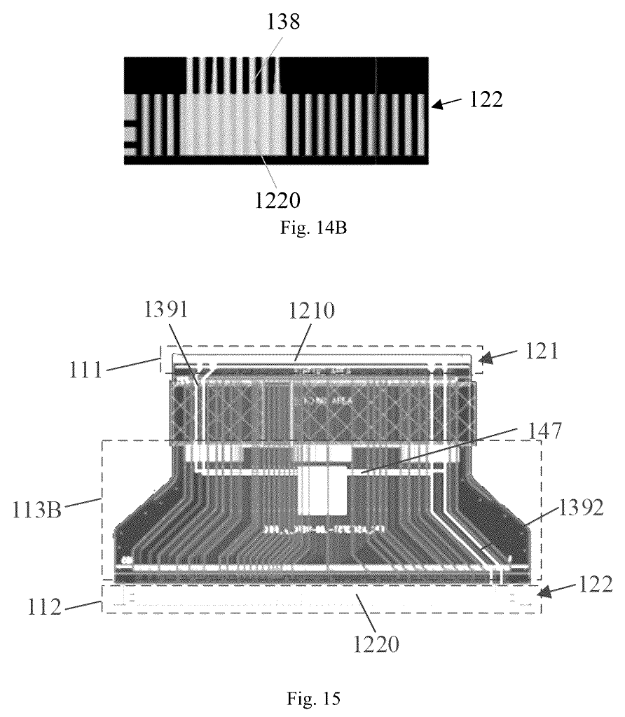

FIG. 14A is a partial schematic diagram of a first pad structure in another flexible circuit board provided by an embodiment of the present disclosure, and FIG. 14B is a partial schematic diagram of a second pad structure in another flexible circuit board provided by an embodiment of the present disclosure.

As illustrated by FIG. 14A and FIG. 14B, the first pad structure 121 includes M first conductive pads 1210, and the second pad structure 122 includes N second conductive pads 1220; the plurality of signal transmission lines 130 include a third signal transmission line 138, the third signal transmission line 138 includes a first end and a second end, and the first end of the third signal transmission line 138 includes P branches 1381; the P branches 1381 at the first end of the third signal transmission line 138 are respectively connected with P first conductive pads 1210, and the second end of the third signal transmission line 138 is connected with one second conductive pad 1220. P is a positive integer greater than or equal to 2 and less than N, and M is greater than N. Therefore, the flexible circuit board can reduce the number of signal transmission lines in the transmission line region 113 through the above structure, thereby making the signal transmission line have a larger line width or increasing the spacing between signal transmission lines, and improving the stability of the flexible circuit board; on the other hand, the flexible circuit board can also reduce the number of second conductive pads in the second pad structure.

For example, as illustrated by FIG. 13A and FIG. 13B, the value of P may be 2. In this case, the first end of the third signal transmission line 138 includes two branches 1381; the two branches 1381 at the first end of the third signal transmission line 138 are respectively connected with two first conductive pads 1210, and the second end of the third signal transmission line 138 is connected with one second conductive pad 1220. Of course, the embodiments of the present disclosure include but are not limited thereto, and the value of P may also be 3, 4, 5, 6, 7, 8, etc.

FIG. 15 is a layout diagram of a flexible circuit board provided by an embodiment of the present disclosure. As illustrated by FIG. 15, the first pad structure 121 includes M first conductive pads 1210, and the second pad structure 122 includes Q second conductive pads 1220; the plurality of signal transmission lines 130 include a fourth signal transmission line 1391 and a fifth signal transmission line 1392; the fourth signal transmission line 1391 extends from the first pad region 111 to the first double-layer region 113B, the fourth signal transmission line 1391 includes a first end located in the first pad region 111 and a second end located in the first double-layer region 113B; the fifth signal transmission line 1392 extends from the first pad region 111 through the first double-layer region 113B to the second pad region 112, and the fifth signal transmission line 1392 includes a first end located in the first pad region 111 and a second end located in the second pad region 112. The second conductive layer 140 further includes a transverse transmission line 147, the transverse transmission line 147 is connected with the second end of the fourth signal transmission line 1391 through a third via hole passing through the substrate layer 110, and connected with the fifth signal transmission line 1392 through a fourth via hole passing through the substrate layer 110. In this way, the flexible circuit board 100 can connect the fourth signal transmission line 1391 to the fifth signal transmission line 1392 through the fourth signal transmission line 1391 and the transverse transmission line 147 mentioned above, thereby reducing the number of signal transmission lines in the transmission line region 113, making the signal transmission line have a larger line width or increasing the spacing between signal transmission lines, and improving the stability of the flexible circuit board. It should be noted that in the embodiments of the present disclosure, for the case where the transverse transmission line is connected with the fourth signal transmission line and the second signal transmission line through via holes passing through the substrate layer, please refer to FIG. 9 and the related descriptions. For the specific structures and arrangements of the third via hole and the fourth via hole, please refer to the first via in FIG. 9.

It should be noted that, without conflict, the method of reducing the number of signal transmission lines as illustrated by FIG. 13A to FIG. 13B, the method of reducing the number of signal transmission lines as illustrated by FIG. 14A to FIG. 14B, and the method of reducing the number of signal transmission lines as illustrated by FIG. 15A to FIG. 15B may exist alone or in combination, the embodiments of the present disclosure are not limited in this aspect.

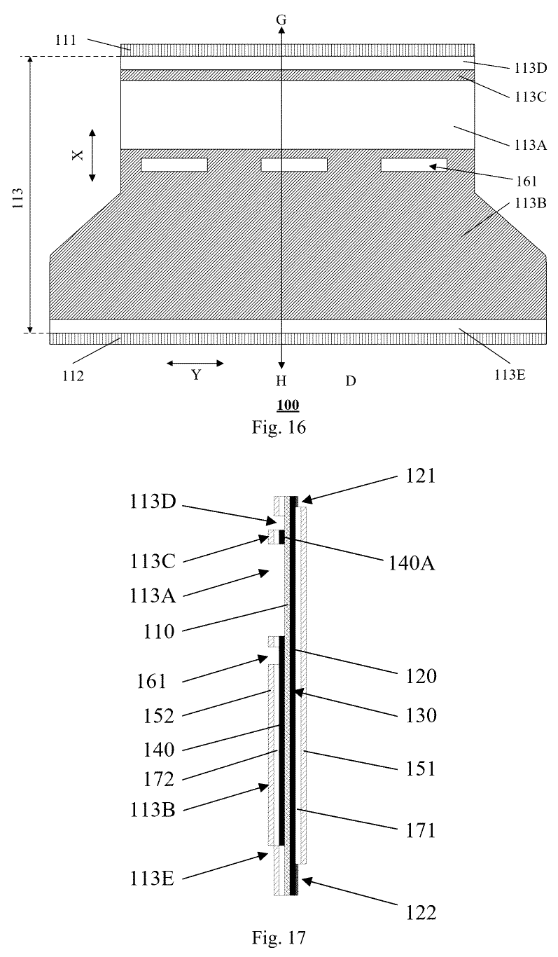

FIG. 16 is a planar schematic diagram of a flexible circuit board provided by an embodiment of the present disclosure, and FIG. 17 is a cross-sectional schematic diagram of a flexible circuit board along a line GH in FIG. 16 provided by an embodiment of the present disclosure.

As illustrated by FIG. 16 and FIG. 17, the flexible circuit board 100 includes a substrate layer 110 and a first conductive layer 120; the substrate layer 110 includes a first pad region 111, a second pad region 112, and a transmission line region 113 located between the first pad region 111 and the second pad region 112. The first pad region 111, the transmission line region 113, and the second pad region 112 may be arranged along the first direction X; the first conductive layer 120 is located at the first side of the substrate layer 110 and includes a first pad structure 121, a second pad structure 122, and a plurality of signal transmission lines 130 extending in the first direction; the first pad structure 121 is located in the first pad region 111, the second pad structure 122 is located in the second pad region 112, and the plurality of signal transmission lines 130 are located in the transmission line region 113.

As illustrated by FIG. 16 and FIG. 17, unlike the flexible circuit board shown in FIG. 2, the transmission line region 113 includes a second double-layer region 113C, a first single-layer region 113A, and a first double-layer region 113B arranged along the first direction X, but does not include a third double-layer region connecting the first double-layer region and the second double-layer region. In the first single-layer region 113A, the first side of the substrate layer 110 is provided with the first conductive layer 120, and the second side of the substrate layer 110 is not provided with a conductive structure. In the first double-layer region 113B, the first side of the substrate layer 110 is provided with the first conductive layer 120, and the second side of the substrate layer 110 is provided with a second conductive layer 140. In the second double-layer 113C, the first side of the substrate layer 110 is provided with the first conductive layer 120, and the second side of the substrate layer 110 is provided with the third conductive layer 140A. The second side and the first side mentioned above are opposite sides of the substrate layer 110. It can be seen that the “single-layer” and “double-layer” in the “single-layer region” and “double-layer region” in the embodiments of the present disclosure refer to the number of conductive layers included in the corresponding region, and are not used to limit the number of other non-conductive layers.

In the flexible circuit board provided by the embodiments of the present disclosure, the first single-layer region only includes a single conductive layer, thus having good bending performance and less prone to fracture and generating excessive stress. Therefore, by providing the second double-layer region, the first single-layer region, and the first double-layer region in the transmission line region, the flexible circuit board can be bent or curved in the first single-layer region, thereby having good bending performance and avoiding significant stress or fracture in the first single-layer region. At the same time, the flexible circuit board can also use the second conductive layer in the first double-layer region to provide electromagnetic protection and impedance matching for signal transmission lines, thereby avoiding display defects caused by poor data transmission stability, improving the anti-electromagnetic interference ability and electromagnetic compatibility (EMC performance) of the flexible circuit board, and allowing the flexible circuit board to have a wider range of applications and scenarios. In addition, the flexible circuit board can also use the third conductive layer in the second double-layer region to provide electromagnetic protection and impedance matching for signal transmission lines, thereby further improving the anti-electromagnetic interference ability and electromagnetic compatibility (EMC performance) of the flexible circuit board.

In some examples, the second conductive layer 140 and the third conductive layer 140A are arranged in the same layer. That is to say, the second conductive layer 140 and the third conductive layer 140A can be formed of the same conductive material layer through the same patterning process. Of course, the embodiments of the present disclosure include but are not limited thereto, the second conductive layer 140 and the third conductive layer 140A may also be formed of different materials through different patterning processes. It should be noted that even if the second conductive layer 140 and the third conductive layer 140A are formed of different materials through different patterning processes, both the second conductive layer 140 and the third conductive layer 140A can be located at the side of the substrate layer 110 away from the first conductive layer 120, or on the surface of the substrate layer 110 away from the first conductive layer 120.

For example, the substrate layer 110 may be a flexible substrate layer 110, and the material of the flexible substrate layer 110 may be polyimide, etc. The material of the first conductive layer 120 may be the conductive metal material such as copper, aluminum, silver, etc., and the material of the second conductive layer 140 may also be the conductive metal material such as copper, aluminum, silver, etc.

In some examples, because the first single-layer region 113A only includes one conductive layer (i.e., the first conductive layer 120) and has good bending or curving performance, at least part of the first single-layer region can serve as a bending region. That is, bending or curving process can be performed in the first single-layer region. The first double-layer region 113B and the second double-layer region 113C have two conductive layers and can serve as flat regions.

It is worth noting that the second conductive layer 140 of the first double-layer region 113B in the flexible circuit board 100 provided by the embodiments of the present disclosure can not only be used for electromagnetic protection and impedance matching of the signal transmission line 130, but also for other functions. For example, the second conductive layer 140 may be provided with a conductive structure connected with part of the signal transmission lines 130 to reduce resistance; alternatively, the second conductive layer 140 may be provided with a conductive structure to electrically connect a plurality of signal transmission lines 130 that transmit the same signal, to improve the uniformity and stability of the signal.

Similarly, the third conductive layer 140A of the second double-layer region 113C in the flexible circuit board 100 provided by the embodiments of the present disclosure can not only be used for electromagnetic protection and impedance matching of the signal transmission line 130, but also for other functions. For example, the third conductive layer 140A may be provided with a conductive structure connected with part of the signal transmission lines 130 to reduce resistance; alternatively, the third conductive layer 140A may be provided with a conductive structure to electrically connect a plurality of signal transmission lines 130 that transmit the same signal, to improve the uniformity and stability of the signal.

In some examples, the flexible circuit board may also be bent to form a U-shaped structure, the U-shaped structure includes a first flat part, a second flat part, and a connection part located between the first flat part and the second flat part. The connection part connects the first flat part and the second flat part to partially enclose a storage space; the storage space can be used to arrange the backboard and the backlight module; the backlight module can adopt a side-in backlight module or a straight-down backlight module. The first double-layer region is located at the second flat part, the first single-layer region and the second double-layer region are located at the connection part, the second double-layer region is located at the bottom of the connection part away from the storage space, and the first single-layer region is located between the bottom and the second flat part. Therefore, the flexible circuit board can use the first flat part to arrange the first double-layer region, use the bottom of the connection part to arrange the second double-layer region, and use the first single-layer region for bending or curving. It should be noted that, for the specific arrangements of the U-shaped structure mentioned above, please refer to the relevant descriptions in FIG. 4A and FIG. 4B, which will not be repeated here.

In some examples, as illustrated by FIG. 16 and FIG. 17, the flexible circuit board 100 further includes a second single-layer region 113D and a third single-layer region 113E; the second single-layer region 113D is located between the second double-layer region 113C and the first pad region 111; the third single-layer region 113E is located between the first double-layer region 113B and the second pad region 112. The second single-layer region 113D can serve as a bending region between the bottom 232 of the connection part 230 away from the storage space 250 and the second flat part 220, and the third single-layer region 113E can serve as a transition region between the second pad region 112 and the first double-layer region 113B.

In some examples, as illustrated by FIG. 16 and FIG. 17, the first pad region 111, the second single-layer region 113D, the second double-layer region 113C, the first single-layer region 113A, the first double-layer region 113B, and the third single-layer region 113E are sequentially arranged in the first direction.

It is worth noting that the second double-layer region mentioned above is the transitional region between the two bending regions, the second double-layer region can also serve as a support to prevent the flexible circuit board from being excessively bent into a sharp angle and causing signal transmission line breakage. In addition, an interconnection line may be provided in the third conductive layer to connect signal transmission lines that transmit the same signal in the first conductive layer, thereby improving the uniformity of the signals on these signal transmission lines.

In some examples, as illustrated by FIG. 16 and FIG. 17, the flexible circuit board 100 further includes a first protection layer 151, a second protection layer 152, and a first exposing opening 161; the first protection layer 151 is located in the transmission line region 113, and at the side of the first conductive layer 120 away from the substrate layer 110; the second protection layer 152 is located in the first double-layer region 113B, and at the side of the second conductive layer 140 away from the substrate layer 110; the first exposing opening 161 is located in the second protection layer 152 and is configured to expose the second conductive layer 140, so that the second conductive layer 140 can be connected with an external conductive structure to provide voltage or electrical signals to various conductive structures in the second conductive layer 140.

In some examples, as illustrated by FIG. 16 and FIG. 17, the first exposing opening 161 is located at the side of the center of the first double-layer region 113B close to the first single-layer region 113A in the first direction. Of course, the embodiments of the present disclosure include but are not limited thereto, and the first exposing opening may also be provided in other positions.

In some examples, as illustrated by FIG. 16 and FIG. 17, the flexible circuit board 100 includes a plurality of first exposing openings 161 arranged along the second direction Y intersecting with the first direction X. For example, the flexible circuit board 100 includes three first exposing openings 161 arranged at intervals along the second direction Y. Therefore, the second conductive layer can have a more uniform electrical potential.

In some examples, as illustrated by FIG. 16 and FIG. 17, the flexible circuit board 100 may further include a first adhesive layer 171 and a second adhesive layer 172; the first adhesive layer 171 is located between the first conductive layer 120 and the first protection layer 151; and the second adhesive layer 172 is located between the second conductive layer 140 and the second protection layer 152. It should be noted that when the second adhesive layer 172 is provided, the first exposing opening 161 also penetrates through the second adhesive layer 172 to expose the second conductive layer 140.

In some examples, the flexible circuit board further includes a conductive tape that is in contact with the second conductive layer through the first exposing opening mentioned above, thereby grounding the second conductive layer. It should be noted that, for the specific arrangements of the conductive tape mentioned above, please refer to the relevant descriptions in FIG. 5, which will not be repeated here.

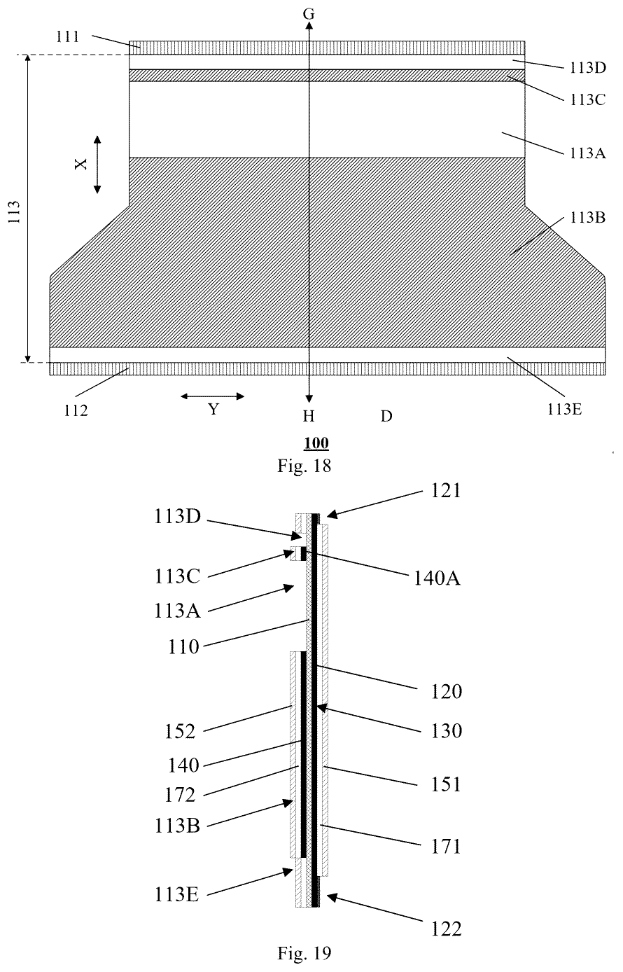

FIG. 18 is a planar schematic diagram of a flexible circuit board provided by an embodiment of the present disclosure, and FIG. 19 is a cross-sectional schematic diagram of a flexible circuit board along a line JK in FIG. 18 provided by an embodiment of the present disclosure.

As illustrated by FIG. 18 and FIG. 19, unlike the flexible circuit board shown in FIG. 15 and FIG. 16, the flexible circuit board is not provided with the first exposing opening mentioned above. The flexible circuit board 100 includes a substrate layer 110 and a first conductive layer 120; the substrate layer 110 includes a first pad region 111, a second pad region 112, and a transmission line region 113 located between the first pad region 111 and the second pad region 112. The first pad region 111, the transmission line region 113, and the second pad region 112 may be arranged along the first direction X; the first conductive layer 120 is located at the first side of the substrate layer 110 and includes a first pad structure 121, a second pad structure 122, and a plurality of signal transmission lines 130 extending in the first direction; the first pad structure 121 is located in the first pad region 111, the second pad structure 122 is located in the second pad region 112, and the plurality of signal transmission lines 130 are located in the transmission line region 113.

As illustrated by FIG. 18 and FIG. 19, the transmission line region 113 includes a first single-layer region 113A and a first double-layer region 113B arranged along the first direction X. In the first single-layer region 113A, the first side of the substrate layer 110 is provided with the first conductive layer 120, and the second side of the substrate layer 110 is not provided with a conductive structure. In the first double-layer region 113B, the first side of the substrate layer 110 is provided with the first conductive layer 120, and the second side of the substrate layer 110 is not provided with the second conductive layer 140. The second side and the first side are opposite sides of the substrate layer 110. It can be seen that the “single-layer” and “double-layer” in the “single-layer region” and “double-layer region” in the embodiments of the present disclosure refer to the number of conductive layers included in the corresponding region, and are not used to limit the number of other non-conductive layers.

In the flexible circuit board provided by the embodiments of the present disclosure, the first single-layer region only includes a single conductive layer, thus having good bending performance and less prone to fracture and generating excessive stress. Therefore, by providing the second double-layer region, the first single-layer region, and the first double-layer region in the transmission line region, the flexible circuit board can be bent or curved in the first single-layer region, thereby having good bending performance and avoiding significant stress or fracture in the first single-layer region. At the same time, the flexible circuit board can also use the second conductive layer in the first double-layer region to provide electromagnetic protection and impedance matching for signal transmission lines, thereby avoiding display defects caused by poor data transmission stability, improving the anti-electromagnetic interference ability and electromagnetic compatibility (EMC performance) of the flexible circuit board, and allowing the flexible circuit board to have a wider range of applications and scenarios. In addition, the flexible circuit board can also use the third conductive layer in the second double-layer region to provide electromagnetic protection and impedance matching for signal transmission lines, thereby further improving the anti-electromagnetic interference ability and electromagnetic compatibility (EMC performance) of the flexible circuit board.

In some examples, as illustrated by FIG. 18 and FIG. 19, the transmission line region 113 further includes a second double-layer region 113C, the second double-layer region 113C is located at the side of the first single-layer region 113A away from the first double-layer region 113B in the first direction. That is to say, the first single-layer region 113A is arranged between the first double-layer region 113B and the second double-layer region 113C. In the second double-layer region 113C, the first side of the substrate layer 110 is provided with the first conductive layer 120, and the second side of the substrate layer 110 is provided with the third conductive layer 140A. Therefore, the flexible circuit board 100 can use other relatively flat parts to arrange the second double-layer region 113C mentioned above, and use the third conductive layer 140A in the second double-layer region 113C to provide electromagnetic protection and impedance matching for the signal transmission lines, thereby avoiding display defects caused by poor data transmission stability, and further improving the anti-electromagnetic interference ability and electromagnetic compatibility (EMC performance) of the flexible circuit board 100.

In some examples, as illustrated by FIG. 18 and FIG. 19, the flexible circuit board 100 further includes a second single-layer region 113D and a third single-layer region 113E; the second single-layer region 113D is located between the second double-layer region 113C and the first pad region 111; the third single-layer region 113E is located between the first double-layer region 113B and the second pad region 112. The second single-layer region 113D can serve as a bending region between the bottom 232 of the connection part 230 away from the storage space 250 and the second flat part 220, and the third single-layer region 113E can serve as a transition region between the second pad region 112 and the first double-layer region 113B.

In some examples, as illustrated by FIG. 18 and FIG. 19, the first pad region 111, the second single-layer region 113D, the second double-layer region 113C, the first single-layer region 113A, the first double-layer region 113B, and the third single-layer region 113E are sequentially arranged in the first direction.

In some examples, as illustrated by FIG. 18 and FIG. 19, the flexible circuit board 100 further includes a first protection layer 151, a second protection layer 152, and a first exposing opening 161; the first protection layer 151 is located in the transmission line region 113, and at the side of the first conductive layer 120 away from the substrate layer 110; the second protection layer 152 is located in the first double-layer region 113B, and at the side of the second conductive layer 140 away from the substrate layer 110; the first exposing opening 161 is located in the second protection layer 152 and is configured to expose the second conductive layer 140, so that the second conductive layer 140 can be connected with an external conductive structure to provide voltage or electrical signals to various conductive structures in the second conductive layer 140.

In some examples, as illustrated by FIG. 18 and FIG. 19, the flexible circuit board 100 may further include a first adhesive layer 171 and a second adhesive layer 172; the first adhesive layer 171 is located between the first conductive layer 120 and the first protection layer 151; and the second adhesive layer 172 is located between the second conductive layer 140 and the second protection layer 152. It should be noted that when the second adhesive layer 172 is provided, the first exposing opening 161 also penetrates through the second adhesive layer 172 to expose the second conductive layer 140.

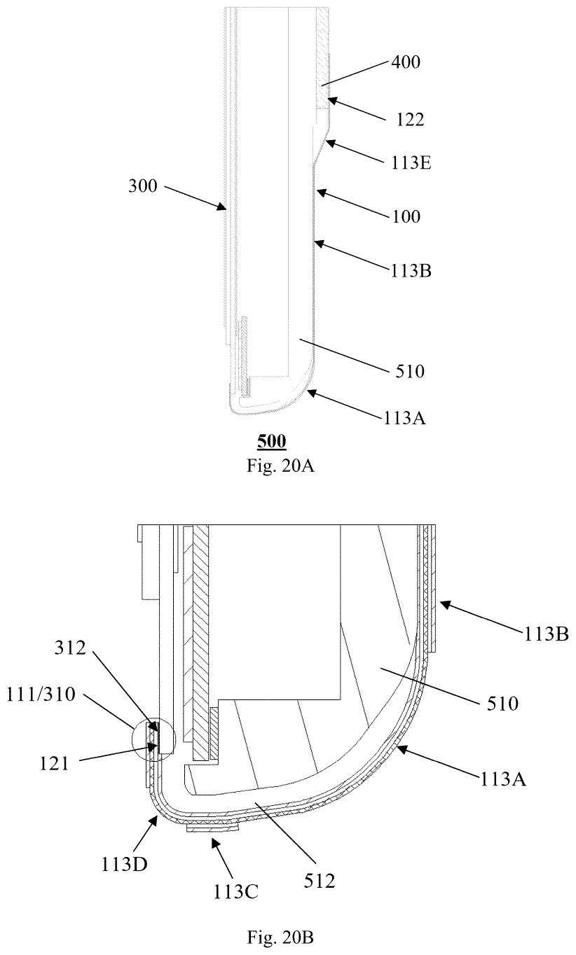

At least one embodiment of the present disclosure further provides a display device 500. FIG. 20A is a structural schematic diagram of a display device provided by an embodiment of the present disclosure, and FIG. 20B is a partial enlarged diagram of a display device provided by an embodiment of the present disclosure. As illustrated by FIG. 20A and FIG. 20B, the display device 500 includes a display panel 300 and the above flexible circuit board 100. Because of the good bending performance of the flexible circuit board, and less prone to breakage and excessive stress generation, the display device using this flexible circuit board can achieve narrow frame design while avoiding light leakage and Mura defects caused by excessive tension on the display panel generated by the flexible circuit board. On the other hand, because of the strong anti-electromagnetic interference ability and electromagnetic compatibility (EMC performance) of the flexible circuit board, the display device using the flexible circuit board also has anti-electromagnetic interference ability and electromagnetic compatibility (EMC performance), thus having a wider range of applications and scenarios.

In some examples, the above display device may be the electronic device with display function such as a mobile phone, a computer, a tablet, a television, an electronic picture frame, a navigation device, an in-car display, a medical display, etc. It should be noted that because of the strong anti-electromagnetic interference ability and electromagnetic compatibility (EMC performance), the display device has strong stability when used as a vehicle mounted display or medical display.

In some examples, as illustrated by FIG. 20A and FIG. 20B, the display device 500 further includes a backboard 510 and a driving circuit board 400; the backboard 510 is located on one side of display panel 300; the driving circuit board 400 is located at the side of the backboard 510 away from the display panel 300. The display panel 300 includes a bonding region 310 and a plurality of bonding pads 312 located in the bonding region 310. The backboard 510 includes a bottom frame 512. The flexible circuit board 100 is bent from the bonding region to the side of the backboard 510 away from the display panel 300; the first pad structure 121 is connected with the plurality of bonding pads 312, and the second pad structure 122 is connected with the driving circuit board 400. Therefore, the driving circuit board 400 can transmit display data to the display panel 300 through the flexible circuit board 100 to drive the display panel 300 to emit light and display. Moreover, because the driving circuit board 400 is located at the backlight side of the display panel 300, and the flexible circuit board 100 is connected with the display panel 300 and the driving circuit board 400 through bending, the driving circuit board 400 does not occupy too much area, thus achieving a narrow frame design.

In some examples, as illustrated by FIG. 20A and FIG. 20B, at least part of the first double-layer region 113B is located at the side of the backboard away from the display panel 300, and at least part of the first single-layer region 113A is a bending region surrounding the bottom frame 512. In this way, the first single-layer region 113A of the flexible circuit board 100 can serve as the bending part of the flexible circuit board 100, while the first double-layer region 113B can be the flat part of the flexible circuit board 100 located at the backlight side of the display panel 300. Therefore, the display device can utilize the flexible circuit board to have both good bending performance and strong anti-electromagnetic interference ability and electromagnetic compatibility (EMC performance).

On the other hand, because the flexible circuit board 100 uses the first single-layer region 113A as the bending part, the stress generated by the first single-layer region 113A is relatively small, which will not cause significant tension on the bonding region of the display panel 300, thereby avoiding the exposure of backlight below the display panel 300 to cause defects such as light leakage and Mura.

The following points need to be explained:
(1) In the drawings of the embodiment of the present disclosure, only the structure related to the embodiment of the present disclosure is involved, and other structures can refer to the general design.
(2) Features in the same embodiment and different embodiments of the present disclosure can be combined with each other without conflict.

The above is only the specific embodiment of this disclosure, but the protection scope of this disclosure is not limited to this. Any person familiar with the technical field can easily think of changes or substitutions within the technical scope disclosed in this disclosure, and they should be included in the protection scope of this disclosure. Therefore, the scope of protection of this disclosure should be based on the scope of protection of the claims.

1. A flexible circuit board, comprising:
a substrate layer, comprising a first pad region, a second pad region, and a transmission line region between the first pad region and the second pad region; and
a first conductive layer, at a first side of the substrate layer and comprising a first pad structure, a second pad structure, and a plurality of signal transmission lines extending along a first direction, wherein the first pad structure is in the first pad region, the second pad structure is in the second pad region, the plurality of signal transmission lines are in the transmission line region, and the transmission line region comprises a first single-layer region and a first double-layer region arranged along the first direction;
in the first single-layer region, the first side of the substrate layer is provided with the first conductive layer, and a second side of the substrate layer is not provided with a conductive structure, in the first double-layer region, the first side of the substrate layer is provided with the first conductive layer, and the second side of the substrate layer is provided with a second conductive layer, the second side and the first side are opposite sides of the substrate layer.

2. The flexible circuit board according to claim 1, wherein at least part of the first single-layer region is a bending region, and at least part of the first double-layer region is a flat region.

3. The flexible circuit board according to claim 1, wherein the transmission line region further comprises:
a second double-layer region, at a side of the first single-layer region away from the first double-layer region in the first direction,
wherein, in the second double-layer region, the first side of the substrate layer is provided with the first conductive layer, and the second side of the substrate layer is provided with a third conductive layer.

4. The flexible circuit board according to claim 3, wherein the flexible circuit board is bent to form a U-shaped structure, the U-shaped structure comprises a first flat part, a second flat part, and a connection part between the first flat part and the second flat part, the connection part connects the first flat part and the second flat part to partially enclose a storage space;
at least part of the first double-layer region is at the second flat part, at least part of the first single-layer region and at least part of the second double-layer region are at the connection part, at least part of the second double-layer region is at a bottom of the connection part away from the storage space, and at least part of the first single-layer region is between the bottom and the second flat part.

5. The flexible circuit board according to claim 3, wherein the third conductive layer comprises a first interconnection line extending along a second direction intersecting with the first direction;
the plurality of signal transmission lines comprise a plurality of first signal transmission lines, the plurality of first signal transmission lines are configured to transmit same electrical signals, and the plurality of first signal transmission lines are respectively electrically connected with the first interconnection line.

6-7. (canceled)

8. The flexible circuit board according to claim 3, further comprising:
a second single-layer region, between the second double-layer region and the first pad region; and
a third single-layer region, between the first double-layer region and the second pad region.

9. The flexible circuit board according to claim 1, wherein the plurality of signal transmission lines comprise:
a high-frequency signal transmission line, configured to transmit a high-frequency signal; and
a plurality of first ground lines,
wherein two sides of the high-frequency signal transmission line in a second direction intersecting with the first direction are respectively provided with at least one of the plurality of first ground lines, in the first double-layer region, the second conductive layer is connected with first ground lines at two sides of the high-frequency signal transmission line through first via holes passing through the substrate layer.

10. The flexible circuit board according to claim 9, wherein the high-frequency signal transmission line comprises:
a first high-frequency signal sub-line; and
a second high-frequency signal sub-line,
wherein a polarity of a high-frequency signal on the first high-frequency signal sub-line is different from a polarity of a high-frequency signal on the second high-frequency signal sub-line.

11. The flexible circuit board according to claim 3, wherein the transmission line region further comprises:
a third double-layer region, between the first double-layer region and the second double-layer region, and passing through the first single-layer region to be respectively connected with the first double-layer region and the second double-layer region,
wherein the first single-layer region is also at two sides of the third double-layer region in a second direction, and the second direction intersects with the first direction,
in the third double-layer region, the first side of the substrate layer is provided with the first conductive layer, and the second side of the substrate layer is provided with a fourth conductive layer,
the second conductive layer and the third conductive layer are connected through the fourth conductive layer, and are arranged in a same layer.

12. The flexible circuit board according to claim 11, wherein the plurality of signal transmission lines comprise:
a high-frequency signal transmission line, configured to transmit a high-frequency signal; and
a plurality of first ground lines,
wherein the high-frequency signal transmission line extends from the first double-layer region through the third double-layer region to the second double-layer region, and two sides of the high-frequency signal transmission line in the second direction intersecting with the first direction are respectively provided with at least one of the plurality of first ground lines;
in the first double-layer region, the second conductive layer is connected with first ground lines at two sides of the high-frequency signal transmission line through first via holes passing through the substrate layer, in the third double-layer region, the fourth conductive layer is connected with the first ground lines at two sides of the high-frequency signal transmission line through second via holes passing through the substrate layer.

13. The flexible circuit board according to claim 1, further comprising:
a first protection layer, in the transmission line region and at a side of the first conductive layer away from the substrate layer;
a second protection layer, in the first double-layer region and at a side of the second conductive layer away from the substrate layer; and
a first exposing opening, in the second protection layer and configured to expose the second conductive layer.

14. The flexible circuit board according to claim 13, further comprising:
a conductive tape, at least partially at a side of the second protection layer away from the second conductive layer, and in contact with the second conductive layer through the first exposing opening,
wherein the conductive tape is configured to be connected with a ground terminal.

15-16. (canceled)

17. The flexible circuit board according to claim 1, wherein the plurality of signal transmission lines comprise a second ground line at an outermost side of the plurality of signal transmission lines;
the first conductive layer further comprises:
a conductive grid, at a side of the second ground line away from a center of the plurality of signal transmission lines, and connected with the second ground line; and
a protection line, at a side of the conductive grid away from the second ground line.

18. The flexible circuit board according to claim 17, further comprising:
a first protection layer, in the transmission line region and at a side of the first conductive layer away from the substrate layer;
a second protection layer, in the first double-layer region and at a side of the second conductive layer away from the substrate layer; and
a second exposing opening, in the first protection layer and configured to expose the first conductive layer,
wherein an orthographic projection of the second exposing opening on the substrate layer respectively overlaps with an orthographic projection of the second ground line on the substrate layer and an orthographic projection of the conductive grid on the substrate layer,
the flexible circuit board further comprises a first electromagnetic shielding coating layer, at a side of the first protection layer away from the first conductive layer, and in contact with the second ground line and the conductive grid through the second exposing opening.

19-20. (canceled)

21. The flexible circuit board according to claim 18, further comprising:
a third exposing opening, in the second protection layer and configured to expose the second conductive layer; and
a second electromagnetic shielding coating layer, at a side of the second protection layer away from the second conductive layer, and in contact with the second conductive layer through the third exposing opening.

22. (canceled)

23. The flexible circuit board according to claim 1, wherein the first pad structure comprises M first conductive pads, and the second pad structure comprises M second conductive pads;
the plurality of signal transmission lines comprise a second signal transmission line, the second signal transmission line comprises a first end and a second end, the first end of the second signal transmission line comprises P branches, and the second end of the second signal transmission line comprises P branches;
the P branches at the first end of the second signal transmission line are respectively connected with P first conductive pads, and the P branches at the second end of the second signal transmission line are respectively connected with P second conductive pads, P is a positive integer greater than or equal to 2 and less than M.

24. The flexible circuit board according to claim 1, wherein the first pad structure comprises M first conductive pads, and the second pad structure comprises N second conductive pads;
the plurality of signal transmission lines comprise a third signal transmission line, the third signal transmission line comprises a first end and a second end, and the first end of the third signal transmission line comprises P branches;
the P branches at the first end of the third signal transmission line are respectively connected with P first conductive pads, and the second end of the third signal transmission line is connected with one second conductive pad, P is a positive integer greater than or equal to 2 and less than N, and M is greater than N.

25. The flexible circuit board according to claim 1, wherein the first pad structure comprises M first conductive pads, and the second pad structure comprises Q second conductive pads;
the plurality of signal transmission lines comprise:
a fourth signal transmission line, extending from the first pad region to the first double-layer region, wherein the fourth signal transmission line comprises a first end in the first pad region and a second end in the first double-layer region; and
a fifth signal transmission line, extending from the first pad region through the first double-layer region to the second pad region, and comprising a first end in the first pad region and a second end in the second pad region,
wherein the second conductive layer further comprises a transverse transmission line, the transverse transmission line is connected with the second end of the fourth signal transmission line through a third via hole passing through the substrate layer, and connected with the fifth signal transmission line through a fourth via hole passing through the substrate layer.

26-28. (canceled)

29. A display device, comprising:
a display panel, and
the flexible circuit board according to claim 1.

30. The display device according to claim 29, further comprising:
a backboard, at a side of the display panel; and
a driving circuit board, at a side of the backboard away from the display panel,
wherein the display panel comprises a bonding region and a plurality of bonding pads in the bonding region, the backboard comprises a bottom frame, and the flexible circuit board is bent from the bonding region to a side of the backboard away from the display panel;
the first pad structure is connected with the plurality of bonding pads, and the second pad structure is connected with the driving circuit board.

31. (canceled)
